(19) United States
(12) Patent Application Publication
(10) Pub. No.: US 2024/0178192 A1
(43) Pub. Date: May 30, 2024

(54) SEMICONDUCTOR DEVICE

(71) Applicant: Kioxia Corporation, Tokyo (JP)

(72) Inventor: Yasuo TAKEMOTO, Kamakura Kanagawa (JP)

(21) Appl. No.: 18/522,978

(22) Filed: Nov. 29, 2023

(30) Foreign Application Priority Data
Nov. 30, 2022 (JP) 2022-191649

(51) Int. Cl. H01L 25/065; H01L 23/00; H01L 23/31; H01L 23/498

(52) U.S. Cl. CPC H01L 25/0657; H01L 23/315; H01L 23/49816; H01L 24/08; H01L 24/48; H01L 2224/08113; H01L 2224/08238; H01L 2224/48091; H01L 2224/48132; H01L 2224/48227; H01L 2225/06506; H01L 2225/0651; H01L 2225/06562; H01L 2924/1434; H01L 2924/15311; H01L 2924/183

(57) ABSTRACT

According to one embodiment, a semiconductor device includes a wiring substrate and a first semiconductor chip. The first semiconductor chip has a first surface facing the wiring substrate. The first surface has a groove. The groove extends across the first surface and divides the first surface into a first portion and a second portion. A first bonding layer is between the first portion of the first surface and the wiring substrate. A second bonding layer is between the second portion of the first surface and the wiring substrate. A second semiconductor chip is on the wiring substrate. The second semiconductor chip has a portion inside the groove of the first semiconductor chip. A third bonding layer is between the bottom of the groove and a second surface of the second semiconductor chip.

### CROSS-REFERENCE TO RELATED APPLICATION (S)

This application is based upon and claims the benefit of priority from Japanese Patent Application No. 2022-191649, filed Nov. 30, 2022, the entire contents of which are incorporated herein by reference.

### FIELD

Embodiments described herein relate generally to a semiconductor device.

### BACKGROUND

There is a semiconductor device having multiple chips stacked above a controller chip. In some instances, when a controller chip and stacked chips are sealed using an insulating sealing member, the space filling by the insulating sealing member may be insufficient.

### BRIEF DESCRIPTION OF THE DRAWINGS

FIG. 1 is a plan view in which a semiconductor device according to a first embodiment is seen from above.

FIG. 2 is a cross-sectional view of a semiconductor device according to a first embodiment.

FIG. 3 is another cross-sectional view of a

semiconductor device according to a first embodiment.

FIG. 4 is a plan view in which a semiconductor chip according to a first embodiment is seen from below.

FIG. 5 is an enlarged view of a semiconductor chip and wiring substrate connection region according to a first embodiment.

FIGS. 6A to 6H are schematic views depicting aspects of a semiconductor device manufacturing process according to a first embodiment.

FIG. 7 is a cross-sectional view of a semiconductor device according to a second embodiment.

FIG. 8 is another cross-sectional view of a

semiconductor device according to a second embodiment.

FIG. 9 is an enlarged view of a semiconductor chip and wiring substrate connection region according to a third embodiment.

FIG. 10 is a plan view in which a semiconductor device according to a fourth embodiment is seen from above.

FIG. 11 is a cross-sectional view of a semiconductor device according to a fourth embodiment.

FIG. 12 is a plan view in which a semiconductor device according to a fifth embodiment is seen from above.

FIG. 13 is a semiconductor device according to a fifth embodiment.

### DETAILED DESCRIPTION

Embodiments concern a semiconductor device for which insufficient filling properties of a sealing resin can be avoided.

In general, according to one embodiment, a semiconductor device includes a wiring substrate and a first semiconductor chip. The first semiconductor chip has a first surface facing the wiring substrate. The first surface has a groove. The groove extends across the first surface and divides the first surface into a first portion and a second portion. A first bonding layer is between the first portion of the first surface and the wiring substrate. A second bonding layer is between the second portion of the first surface and the wiring substrate. A second semiconductor chip is on the wiring substrate. The second semiconductor chip has a portion inside the groove of the first semiconductor chip. A third bonding layer is between the bottom of the groove and a second surface of the second semiconductor chip.

Hereinafter, certain example embodiments will be described by referring to the drawings. In order to facilitate understanding of the description, identical reference symbols will be applied, as far as possible, to identical or substantially similar components in the drawings, and redundant description may be omitted.

In each drawing, an X-axis, a Y-axis, and a Z-axis may be shown. The X-axis, the Y-axis, and the Z-axis form right-handed, three-dimensional Cartesian coordinates. The +direction along the Z-axis and the −direction along the Z-axis may be called “upward” and “downward” directions, respectively. Also, planes perpendicular to the X-axis, the Y-axis, or the Z-axis may be called a YZ plane, a ZX plane, or an XY plane, respectively.

### First Embodiment

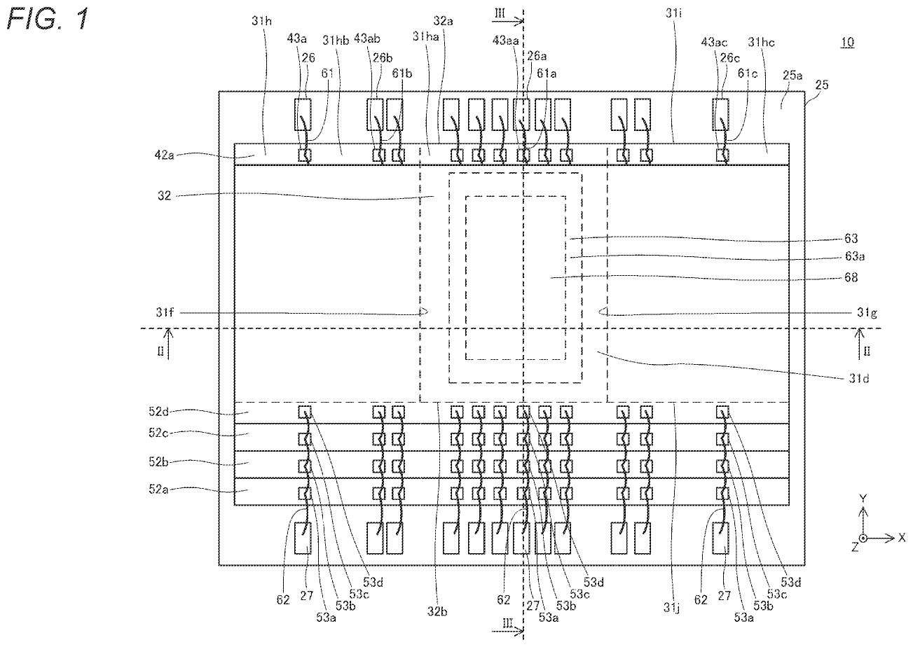

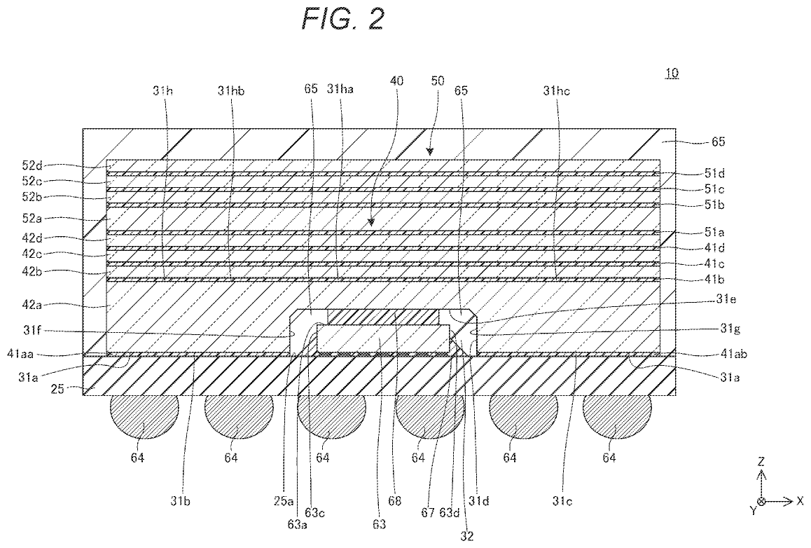

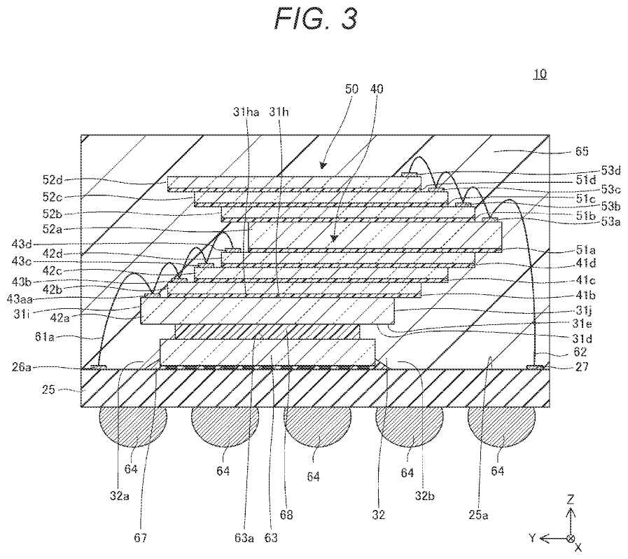

FIG. 1 is a plan view in which a semiconductor device 10 according to the first embodiment is seen from above. FIG. 2 is a cross-sectional view along a section line II-II shown in FIG. 1. FIG. 3 is a cross-sectional view along a section line III-III shown in FIG. 1.

As shown in FIGS. 1 to 3, the semiconductor device 10 includes a wiring substrate 25, stacked chip bodies 40 and 50, bonding wires 61 and 62, a semiconductor chip 63, sealing resins 65 and 67, and a die attach film 68. In order to facilitate understanding of the description, the sealing resins 65 and 67 are not specifically depicted in FIG. 1.

The stacked chip body 40 includes die attach films 41aa, 41ab, 41b, 41c, and 41d and semiconductor chips 42a, 42b, 42c, and 42d. Hereafter, each of the die attach films 41aa, 41ab, 41b, 41c, and 41d may be called a die attach film 41. Each of the semiconductor chips 42a, 42b, 42c, and 42d may be called a semiconductor chip 42.

The stacked chip body 50 includes die attach films 51a, 51b, 51c, and 51d and semiconductor chips 52a, 52b, 52c, and 52d. Hereafter, each of the die attach films 51a, 51b, 51c, and 51d may be called a die attach film 51. Each of the semiconductor chips 52a, 52b, 52c, and 52d may be called a semiconductor chip 52.

The semiconductor chips 42 and 52 are, for example, semiconductor memory chips. Specifically, the semiconductor chips 42 and 52 are NAND flash memory chips in this example. At least one of the semiconductor chips 42 and 52 may be a DRAM chip, or may be a chip having another function. A form of the semiconductor chips 42b to 42d and 52 is a plate form whose upper and lower faces are both faces approximately parallel to the XY plane. A long side and a short side of the face are approximately parallel to the X-axis and the Y-axis respectively.

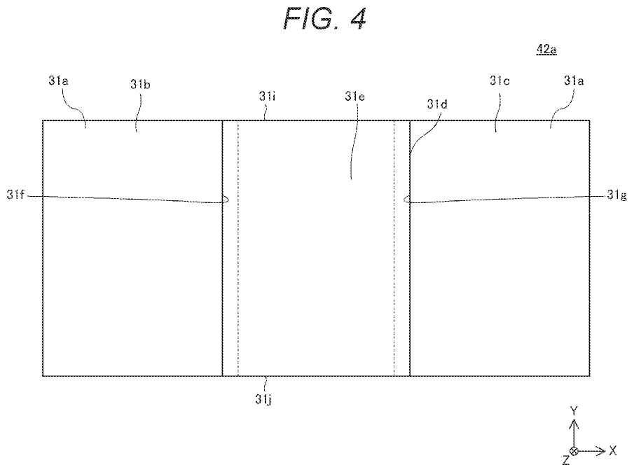

FIG. 4 is a plan view in which the semiconductor chip 42a is seen from below. As shown in FIGS. 1 to 4, the semiconductor chip 42a has a lower main surface side 31a approximately parallel to the XY plane. The lower main surface side 31a is, for example, rectangular. A long side and a short side of the lower main surface side 31a are approximately parallel to the X-axis and the Y-axis respectively.

The semiconductor chip 42a has a groove portion 31d that divides the lower main surface side 31a into a face portion 31b and a face portion 31c. The groove portion 31d extends approximately parallel to the short side of the lower main surface side 31a, that is, approximately parallel to the Y-axis. The groove portion 31d has a bottom face 31e that is approximately parallel to the XY plane. The groove portion 31d has a side face 31f (sidewall) and a side face 31g (sidewall) approximately parallel to the YZ plane.

The groove portion 31d divides the main face 31a in such a way that, for example, the face portions 31b and 31c are rectangular. The form and an area of the face portion 31b are approximately the same as the form and area of the face portion 31c.

An upper face 31h of the semiconductor chip 42a has a rectangular form. The long side and the short side of the face 31h are approximately parallel to the X-axis and the Y-axis respectively.

A distance between the bottom face 31e and the face 31h, that is, a thickness of the semiconductor chip 42d in the groove portion 31d, is, for example, 50 μm. Also, a distance between the main face 31a and the face 31h is, for example, 150 to 200 μm.

The wiring substrate 25 has a face 25a that opposes the face portions 31b and 31c of the semiconductor chip 42a. The face 25a is, for example, rectangular. The long side and the short side of the face 25a are approximately parallel to the X-axis and the Y-axis, respectively.

The die attach film 41aa is provided between the face portion 31b of the semiconductor chip 42a and the face 25a of the wiring substrate 25. An upper face and a lower face of the die attach film 41aa are bonded to the face portion 31b and the face 25a, respectively, whereby the semiconductor chip 42a is fixed to the wiring substrate 25.

The die attach film 41ab is provided between the face portion 31c of the semiconductor chip 42a and the face 25a of the wiring substrate 25. An upper face and a lower face of the die attach film 41ab are bonded to the face portion 31c and the face 25a respectively, whereby the semiconductor chip 42a is fixed to the wiring substrate 25. A thickness of the die attach films 41aa and 41ab is, for example, several tens of micrometers.

A hole portion 32 is formed by the groove portion 31d of the semiconductor chip 42a and the face 25a of the wiring substrate 25, and both ends are open.

Specifically, an inner wall of the hole portion 32 is formed by the bottom face 31e and the side faces 31f and 31g of the groove portion 31 and one portion of the face 25a.

The hole portion 32 extends approximately parallel to the Y-axis, and has an approximately rectangular cross-section. The hole portion 32 has aperture portions 32a and 32b along Y-axis direction.

At least a portion of the semiconductor chip 63 is provided in the hole portion 32. In the present embodiment, all of the semiconductor chip 63 is provided in the hole portion 32. The semiconductor chip 63 is, for example, a semiconductor memory controller chip. The semiconductor chip 63 is electrically connected to the semiconductor chips 42 and 52 and controls the semiconductor chips 42 and 52.

The semiconductor chip 63 has an upper face 63a that opposes the bottom face 31e of the groove portion 31d. The face 63a is, for example, rectangular. The long side and the short side of the face 63a are approximately parallel to the Y-axis and the X-axis, respectively.

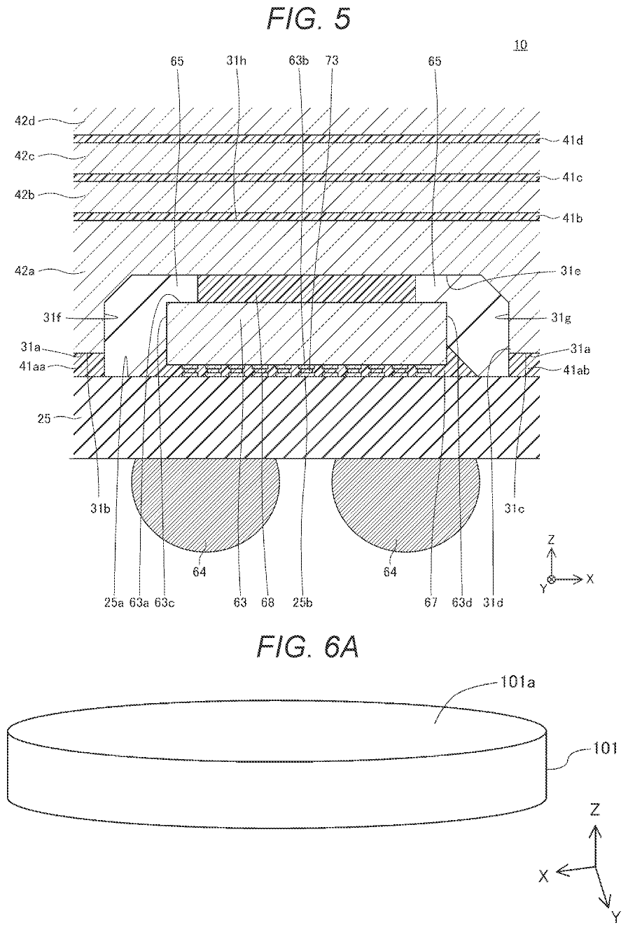

FIG. 5 is an enlarged view of a region where the semiconductor chip 63 and the wiring substrate 25 are connected. As shown in FIGS. 1 to 5, the wiring substrate 25 has multiple substrate electrodes 25b provided on the face 25a.

Multiple solder balls 64 are provided on a lower face of the wiring substrate 25. Also, an electrode pattern (not separately depicted) is formed on the wiring substrate 25. Some of the substrate electrodes 25b can be electrically connected to the multiple solder balls 64 via the electrode pattern of the wiring substrate 25. Some of the substrate electrodes 25b can be electrically connected to a substrate electrode 26 or 27 via the electrode pattern of the wiring substrate 25. Some of the substrate electrodes 25b may be in an electrically floating state.

The semiconductor chip 63 has, on a lower face, multiple chip electrodes 63b respectively provided opposing each one of the multiple substrate electrodes 25b.

The multiple substrate electrodes 25b on the wiring substrate 25 and the multiple chip electrodes 63b on the semiconductor chip 63 are connected via a bump 73. That is, the semiconductor chip 63 is flip chip-connected to the wiring substrate 25. In this manner, the multiple solder balls 64 and the semiconductor chip 63 can be electrically connected.

The sealing resin 67 seals (covers) the semiconductor chip 63, the substrate electrode 25b, the chip electrode 63b, and the bump 73. The semiconductor chip 63, the substrate electrode 25b, the chip electrode 63b, and the bump 73 are insulated and sealed by the sealing resin 67.

The die attach film 68 is provided between at least one portion of the bottom face 31e of the groove portion 31d and at least one portion of the upper face 63a of the semiconductor chip 63.

The present embodiment is such that when the semiconductor chip 63 is seen in plan view in direction perpendicular to the face 63a, the die attach film 68 is provided in a region where the bottom face 31e and the face 63a coincide. Specifically, when seen in plan view, the region is a range within which the face 63a of the semiconductor chip 63 is positioned. The die attach film 68 is provided in the region.

An upper face and a lower face of the die attach film 68 are bonded to the bottom face 31e and the face 63a respectively, whereby the semiconductor chip 42a is fixed to the semiconductor chip 63. A thickness of the die attach film 68 is, for example, several tens of micrometers.

As shown in FIGS. 1 and 3, the wiring substrate 25 includes the multiple substrate electrodes 26. The multiple substrate electrodes 26 are provided arrayed on a straight line approximately parallel to the X-axis in a vicinity of an edge in the +Y-axis direction of the wiring substrate 25.

The semiconductor chips 42a, 42b, 42c, and 42d include multiple chip electrodes 43a, 43b, 43c, and 43d respectively.

The bonding wire 61 electrically connects the substrate electrode 26 and the chip electrodes 43a, 43b, 43c, and 43d.

The multiple chip electrodes 43a are provided on the upper face 31h of the semiconductor chip 42a, farther to a vicinity of an edge 31i on the aperture portion 32a side than to an edge 31j on the aperture portion 32b side. The multiple chip electrodes 43a are arrayed on a straight line approximately parallel to the X-axis.

Specifically, the face 31h includes a face 31ha, which is a face on a side opposite the bottom face 31e of the groove portion 31d, a face 31hb, which is a face on a side opposite the face portion 31b, and a face 31hc, which is a face on a side opposite the face portion 31c.

A chip electrode 43aa, which is one of the multiple chip electrodes 43a, is provided in a vicinity of the edge 31i of the face 31ha. The bonding wire 61 connected to the chip electrode 43aa, that is, a bonding wire 61a, electrically connects a substrate electrode 26a and the chip electrodes 43aa, 43b, 43c, and 43d.

A chip electrode 43ab, which is another one of the multiple chip electrodes 43a, is provided in a vicinity of the edge 31i of the face 31hb. The bonding wire 61 connected to the chip electrode 43ab, that is, a bonding wire 61b, electrically connects a substrate electrode 26b and the chip electrodes 43ab, 43b, 43c, and 43d.

A chip electrode 43ac, which is another one of the multiple chip electrodes 43a, is provided in a vicinity of the edge 31i of the face 31hc. The bonding wire 61 connected to the chip electrode 43ac, that is, a bonding wire 61c, electrically connects a substrate electrode 26c and the chip electrodes 43ac, 43b, 43c, and 43d.

The substrate electrode 26 that is not connected to the bonding wire 61 may be provided on the wiring substrate 25. Also, the chip electrode 43a, 43b, 43c, or 43d that is not connected to the bonding wire 61 may be provided on the semiconductor chip 42a, 42b, 42c, or 42d respectively.

The wiring substrate 25 includes the multiple substrate electrodes 27. The multiple substrate electrodes 27 are provided arrayed on a straight line approximately parallel to the X-axis in a vicinity of an edge in the −Y-axis direction of the wiring substrate 25.

The semiconductor chips 52a, 52b, 52c, and 52d include multiple chip electrodes 53a, 53b, 53c, and 53d respectively. The bonding wire 62 electrically connects the substrate electrode 27 and the chip electrodes 53a, 53b, 53c, and 53d.

The substrate electrode 27 that is not connected to the bonding wire 62 may be provided on the wiring substrate 25. Also, the chip electrode 53a, 53b, 53c, or 53d that is not connected to the bonding wire 62 may be provided on the semiconductor chip 52a, 52b, 52c, or 52d respectively.

As shown in FIGS. 1 to 3, external forms of the semiconductor chips 42 and 52 seen from when above are approximately the same. Thicknesses of the semiconductor chips 42b to 42d and 52b to 52d are approximately the same. The thicknesses of the semiconductor chips 42b to 42d and 52b to 52d are less than a thickness of a portion of the semiconductor chip 42a in which the groove portion 31d is not formed, and less than a thickness of the semiconductor chip 52a.

The semiconductor chip 42b is provided on the upper face 31h of the semiconductor chip 42a in such a way that the chip electrodes 43aa, 43ab, and 43ac are exposed.

Specifically, end faces in the +X-axis direction of the semiconductor chips 42a to 42d and the semiconductor chips 52a to 52d are aligned. End faces in the −X-axis direction of the semiconductor chips 42a to 42d and the semiconductor chips 52a to 52d are aligned.

Both Y-axis direction end faces of the semiconductor chip 42b deviate (offset) in the −Y-axis direction from the Y-axis direction end faces of the semiconductor chip 42a. Both Y-axis direction end faces of the semiconductor chip 42c deviate (offset) in the −Y-axis direction from the Y-axis direction end faces of the semiconductor chip 42b. Both Y-axis direction end faces of the semiconductor chip 42d deviate (offset) in the −Y-axis direction from the Y-axis direction end faces of the semiconductor chip 42c. Both Y-axis direction end faces of the semiconductor chip 52a deviate (offset) in the −Y-axis direction from the Y-axis direction end faces of the semiconductor chip 42d.

That is, the semiconductor chips 42a to 42d, when seen from the −X-axis direction going toward the +X-axis direction, are stacked in a stepped (staggered) form that deviates farther in the −Y-axis direction the higher the semiconductor chip 42 is in the stack. The chip electrodes 43b to 43d are provided on an exposed portion of the upper face of the semiconductor chips 42b to 42d, respectively.

Both Y-axis direction end faces of the semiconductor chip 52b deviate (offset) in the +Y-axis direction from the Y-axis direction end faces of the semiconductor chip 52a. Both Y-axis direction end faces of the semiconductor chip 52c deviate (offset) in the +Y-axis direction from the Y-axis direction end faces of the semiconductor chip 52b. Both Y-axis direction end faces of the semiconductor chip 52d deviate (offset) in the +Y-axis direction from the Y-axis direction end faces of the semiconductor chip 52c.

That is, the semiconductor chips 52a to 52d, when seen from the −X-axis direction going toward the +X-axis direction, are stacked in a stepped (staggered) form that deviates farther in the +Y-axis direction the higher the semiconductor chip 52 is in the stack. The chip electrodes 53a to 53d are provided on an exposed portion of the upper face of the semiconductor chips 52a to 52d, respectively.

The sealing resin 65 seals at least the semiconductor chip 42a. Specifically, the sealing resin 65 buries the stacked chip bodies 40 and 50 and the bonding wires 61 and 62 above the wiring substrate 25. The stacked chip bodies 40 and 50 and the bonding wires 61 and 62 are insulated and sealed by the sealing resin 65.

Also, the sealing resin 65 is also disposed in an interior of the hole portion 32. Specifically, the sealing resin 65 enters an internal space in the hole portion 32 from at least one of the aperture portions 32a and 32b, whereby the internal space is filled. At this time, the sealing resin 65 buries the semiconductor chip 63, the die attach film 68, and the sealing resin 67. The semiconductor chip 63, the die attach film 68, and the sealing resin 67 are insulated and sealed by the sealing resin 65.

The sealing resin 65 comes into contact with at least one portion of the one side face 31f of the groove portion 31d and at least one portion of the side face 63c of the semiconductor chip 63 opposing the side face 31f, and comes into contact with at least one portion of the other side face 31g of the groove portion 31d and at least one portion of the side face 63d of the semiconductor chip 63 opposing the side face 31g.

Also, when the semiconductor chip 63 is seen in plan view from a direction orthogonal to the face 63a, the sealing resin 65 is provided in a region where the bottom face 31e of the groove portion 31d and the face 63a coincide.

When seen in plan view, the relevant region is the range within which the face 63a of the semiconductor chip 63 is positioned, as heretofore described. When seen in plan view, the sealing resin 65 is positioned in such a way as to enclose the die attach film 68 in this region.

### Semiconductor Device Manufacturing Method

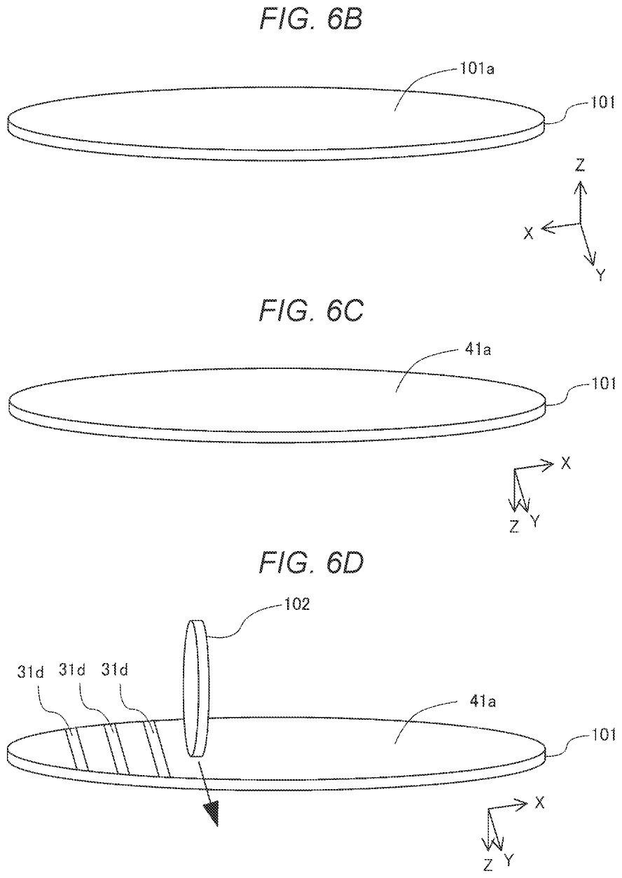

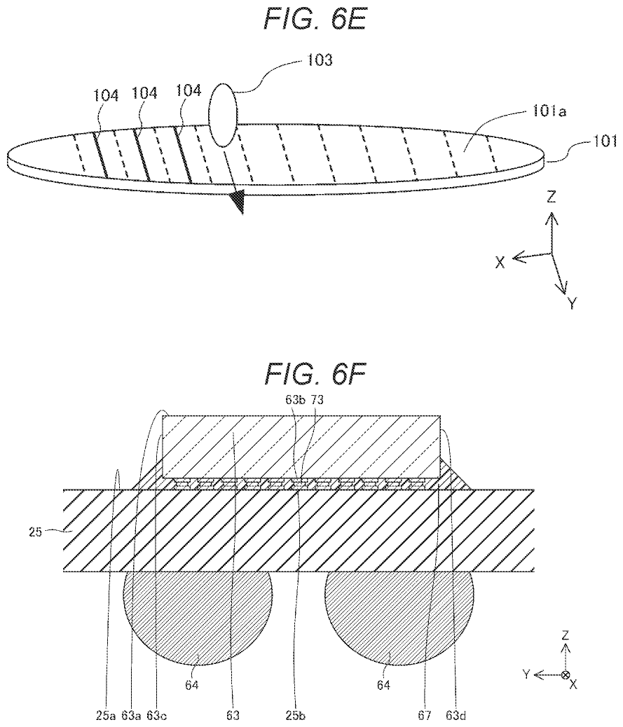

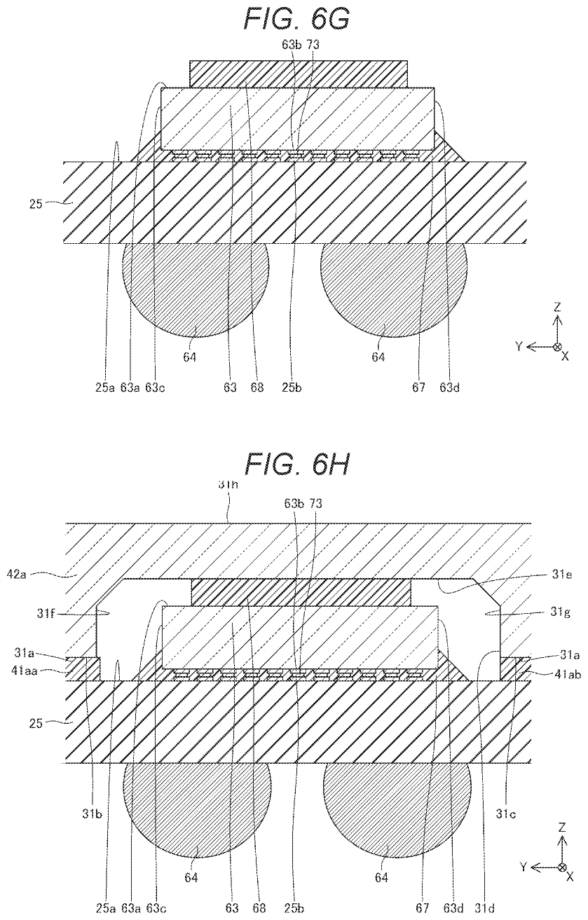

Hereafter, a method of manufacturing the semiconductor device 10 will be described as one example of a semiconductor device manufacturing method according to the present embodiment. Firstly, as shown in FIG. 6A, a memory circuit 101a is formed on an upper face of a semiconductor wafer 101.

Next, as shown in FIG. 6B, a thickness of the semiconductor wafer 101 is reduced by a lower portion of the semiconductor wafer 101 being removed. Specifically, a face on which the memory circuit 101a is not formed, that is, a lower face of the semiconductor wafer 101, is ground using a grinding wheel. By so doing, the thickness of the semiconductor wafer 101 is reduced.

Next, as shown in FIG. 6C, the die attach film 41a is attached to a lower face of the semiconductor wafer 101.

Next, as shown in FIG. 6D, the groove portion 31d is formed in the lower face of the semiconductor wafer 101. In the present embodiment, for example, a blade 102 is inserted several times into the semiconductor wafer 101 in the Y-axis direction in such a way that the groove portion 31d is of a predetermined width. By so doing, a portion of the semiconductor wafer 101 is removed together with the die attach film 41a, whereby the groove portion 31d is formed.

Next, as shown in FIG. 6E, the semiconductor wafer 101 is diced on the upper face of the semiconductor wafer 101 using a blade 103. A dicing line 104 is on the semiconductor wafer 101 between dotted lines that indicate a position of the groove portion 31d (formed in the lower face). A dicing line 104 is formed along the Y-axis direction. Also, although not specifically depicted, a dicing line 104 is also formed along the X-axis direction. The semiconductor wafer 101 is divided into the multiple semiconductor chips 42a by dicing. After this process, the die attach film 41a is divided into the die attach films 41aa and 41ab.

Next, as shown in FIG. 6F, the semiconductor chip 63 is flip chip-connected to the wiring substrate 25. Further, the sealing resin 67 is applied. The semiconductor chip 63, the substrate electrode 25b, the chip electrode 63b, and the bump 73 are insulated and sealed by the sealing resin 67.

Next, as shown in FIG. 6G, die attach film 68 is disposed on the upper face 63a of the semiconductor chip 63.

Next, as shown in FIG. 6H, the semiconductor chip 42a after having been detached from the semiconductor wafer 101 is disposed on the wiring substrate 25. Specifically, the semiconductor chip 42a is bonded to the face 25a of the wiring substrate 25 by the die attach films 41aa and 41ab, and bonded to the face 63a of the semiconductor chip 63 by the die attach film 68.

Next, as shown in FIGS. 1 to 3, the semiconductor chips 42b to 42d are stacked above the semiconductor chip 42a. Furthermore, the bonding wire (s) 61 is formed.

Next, the semiconductor chips 52a to 52d are stacked above the semiconductor chip 42d. Furthermore, the bonding wire (s) 62 is formed.

Next, filling with the sealing resin 65 is carried out. The stacked chip bodies 40 and 50, the bonding wires 61 and 62, the semiconductor chip 63, the die attach film 68, and the sealing resin 67 are insulated and sealed (covered) by the sealing resin 65.

### Advantages

The semiconductor device 10 is such that the space in which the semiconductor chip 63 is housed can be within the groove portion 31d formed under the semiconductor chip 42a.

Also, a distance between the face 63a of the semiconductor chip 63 and the bottom face 31e of the groove portion 31d of the semiconductor chip 42a may be reduced in order to reduce a Z-axis direction thickness of a package of the semiconductor device 10.

If the die attach film 68 is not provided between the semiconductor chip 63 and the semiconductor chip 42a, a narrow space may be formed/left between the semiconductor chip 63 and the semiconductor chip 42a.

The filling of this kind of narrow space with the sealing resin 65 is difficult. As such, a void is likely to be left unfilled by the sealing resin 65. When there is a void of this type, a vapor blowout or the like may occur at the void location during the carrying out a reflow process (high temperature processing), which is not desirable.

In response to this concern, the semiconductor device 10 includes the die attach film 68 between the semiconductor chip 63 and the semiconductor chip 42a to mitigate such a potential problem. Because of this, formation of a void can be avoided, meaning that a good package for the semiconductor device 10 can be achieved.

### Second Embodiment

A semiconductor device according to a second embodiment will be described. For the second embodiment, additional description of those aspects that are the same as (or substantially so) in the first embodiment will be omitted, and differing points will primarily be described. In general, the operational advantages for the first and second embodiments are similar.

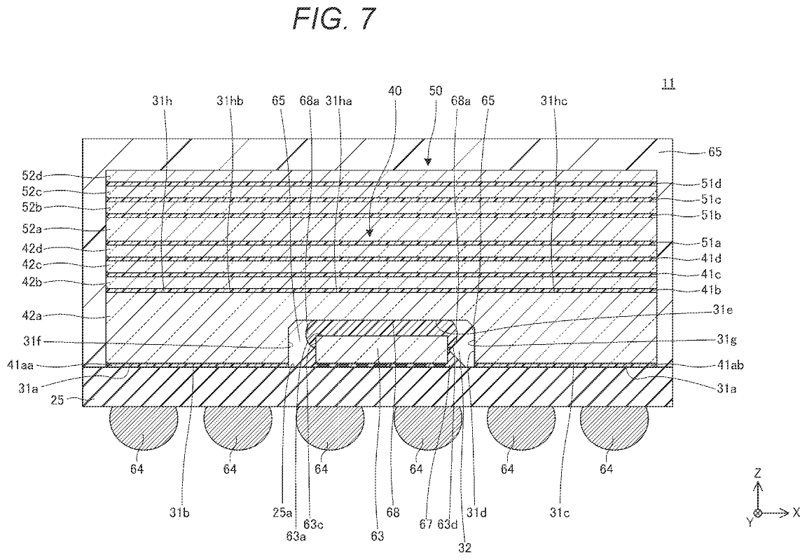

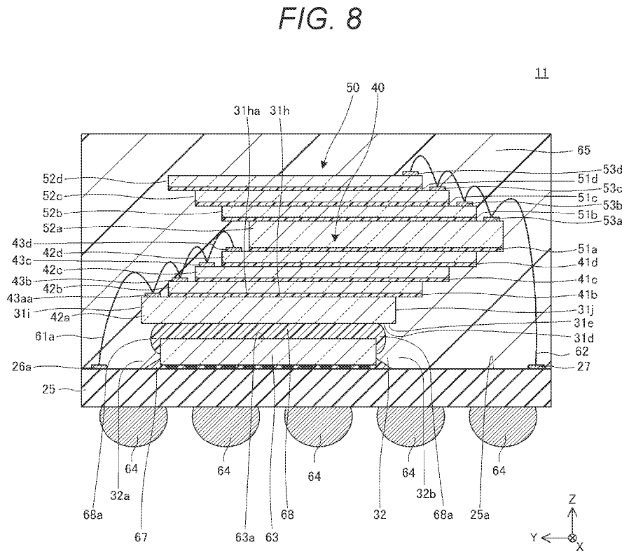

FIGS. 7 and 8 are cross-sectional views of a semiconductor device according to the second embodiment. FIGS. 7 and 8 correspond in position within the semiconductor device in a similar manner as FIGS. 2 and 3, respectively.

As shown in FIGS. 7 and 8, compared with the semiconductor device 10 shown in FIGS. 1 to 5, the semiconductor device 11 differs from the semiconductor device 10 according to the first embodiment in that, when the semiconductor chip 63 is seen in plan view in a direction orthogonal to the face 63a, there is a portion 68a where the die attach film 68 protrudes beyond the face 63a.

In the second embodiment, the protruding portion 68a protrudes in the +X-axis direction, −X-axis direction, the +Y-axis direction, and −Y-axis direction for the die attach film 68. In some examples, the protruding portion 68a protrudes may protruded less than all directions and may protrude in just the direction along the X-axis or Y-axis.

Also, the protruding portion 68a droops downward. A drooping portion of the protruding portion 68a can be in contact with a side face of the semiconductor chip 63. Not being limited to a configuration that droops downward from above, the protruding portion 68a may be of a configuration that spreads while coming into contact with the bottom face 31e of the groove portion 31d in the semiconductor chip 42a, or may be of a configuration that spreads without coming into contact with either the side face of the semiconductor chip 63 or the bottom face 31e.

### Third Embodiment

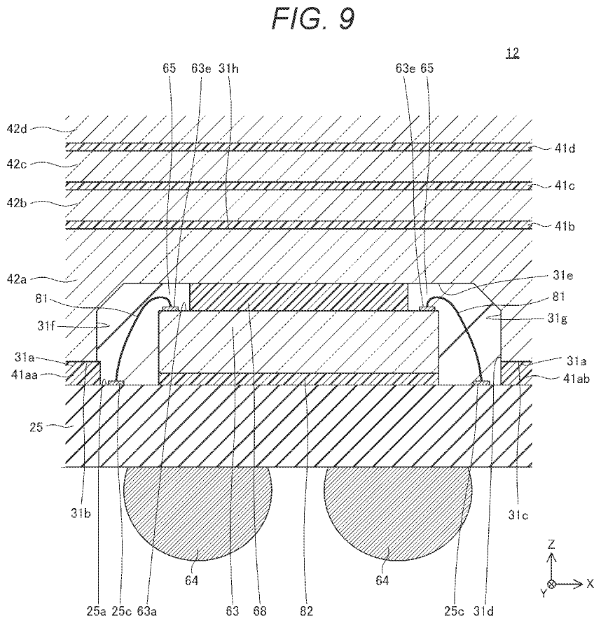

A semiconductor device according to a third embodiment will be described. FIG. 9 is an enlarged view of a semiconductor chip and wiring substrate connection portion according to the third embodiment. As shown in FIG. 9, as compared with the semiconductor device 10 shown in FIGS. 1 to 5, the semiconductor device 12 differs from the semiconductor device 10 according to the first embodiment in that an electrical connection of the semiconductor chip 63 and the wiring substrate 25 is carried out via a bonding wire 81.

Compared with the semiconductor device 10 shown in FIGS. 1 to 5, the semiconductor device 12 includes a substrate electrode 25c, a chip electrode 63e, the bonding wire 81, and a die attach film 82 instead of the substrate electrode 25b, the chip electrode 63b, the sealing resin 67, and the bump 73.

A lower face of the semiconductor chip 63 is bonded to the face 25a of the wiring substrate 25 by the die attach film 82.

The substrate electrode 25c is provided on the face 25a of the wiring substrate 25. The chip electrode 63e is provided on the upper face 63a of the semiconductor chip 63. The bonding wire 81 electrically connects the substrate electrode 25c and the chip electrode 63e.

In the third embodiment, the set of the substrate electrode 25c, the chip electrode 63e, and the bonding wire 81 is provided on each of the −X-axis direction and the +X-axis direction sides of the semiconductor chip 63.

Multiple sets of the substrate electrode 25c, the chip electrode 63e, and the bonding wire 81 may be provided on the X-axis direction sides. Multiple sets of the substrate electrode 25c, the chip electrode 63e, and the bonding wire 81 may also or instead be provided on the Y-axis direction sides of the semiconductor chip 63.

### Fourth Embodiment

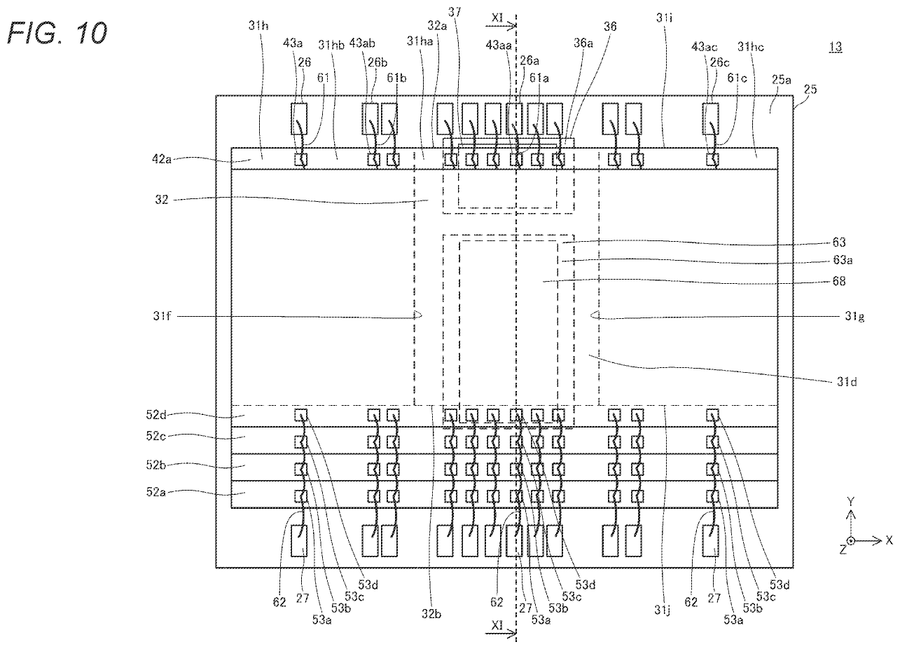

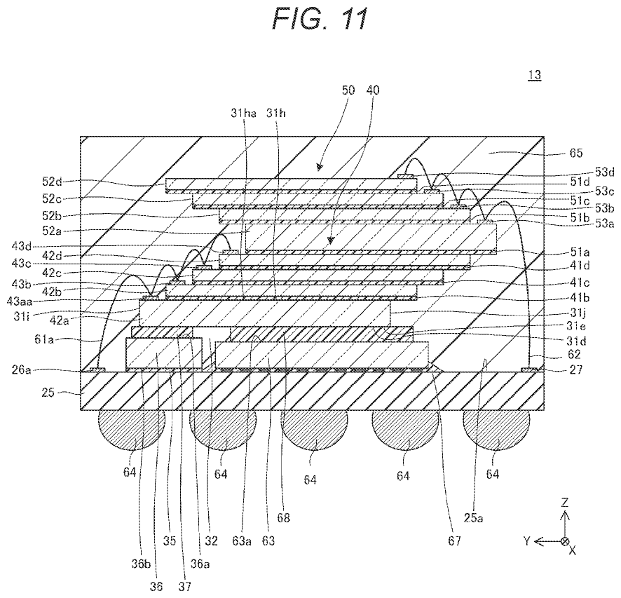

A semiconductor device according to a fourth embodiment will be described. FIG. 10 is a plan view in which a semiconductor device according to the fourth embodiment is seen from above. FIG. 11 is a cross-sectional view along a section line XI-XI shown in FIG. 10. As shown in FIGS. 10 and 11, compared with the semiconductor device 10 shown in FIGS. 1 to 5, the semiconductor device 13 differs from the semiconductor device 10 according to the first embodiment in that one portion in the −Y-axis direction of the semiconductor chip 63 protrudes from the hole portion 32 through the aperture portion 32b.

Compared with the semiconductor device 10 shown in FIGS. 1 to 5, the semiconductor device 13 further includes die attach films 35 and 37 and a spacer 36.

For example, the semiconductor chip 63 may be provided in a position partially separated from the substrate electrode 25c in order to simplify the electrode pattern on the wiring substrate 25.

In such a case, one portion in the −Y-axis direction of the face 63a protrudes beyond the semiconductor chip 42a when the semiconductor chip 63 is seen in plan view in a direction orthogonal to the face 63a. That is, one portion in the semiconductor chip 63 is exposed by protruding from the hole portion 32 through the aperture portion 32b.

However, as a space is now generated in the +Y-axis direction of the semiconductor chip 63, support below the semiconductor chip 42a is weakened. The die attach films 35 and 37 and the spacer 36 support the semiconductor chip 42a from below by being provided in the +Y-axis direction from the semiconductor chip 63.

At least a portion of the spacer 36 may be provided on the aperture portion 32a side of the hole portion 32. Specifically, the spacer 36 is, for example, a semiconductor substrate formed by a semiconductor wafer being diced. A form of the spacer 36 is a plate form whose upper and lower faces are respectively faces 36a and 36b approximately parallel to the XY plane.

The faces 36a and 36b are, for example, rectangular. A long side and a short side of each of the faces 36a and 36b are, for example, approximately parallel to the X-axis and the Y-axis respectively.

One portion in the +Y-axis direction of the face 36a protrudes from the semiconductor chip 42a when the spacer 36 is seen in plan view in a direction perpendicular to the face 36a. That is, one portion in the Y-axis +direction of the spacer 36 is exposed by protruding from the hole portion 32 through the aperture portion 32a.

The die attach film 35 is provided between the spacer 36 and the face 25a of the wiring substrate 25. The lower face 36b of the spacer 36 is bonded to the face 25a of the wiring substrate 25 by the die attach film 35.

The die attach film 37 is provided between the spacer 36 and the bottom face 31e of the groove portion 31d. The upper face 36a of the spacer 36 is bonded to the bottom face 31e of the groove portion 31d in the semiconductor chip 42a by the die attach film 37.

### Fifth Embodiment

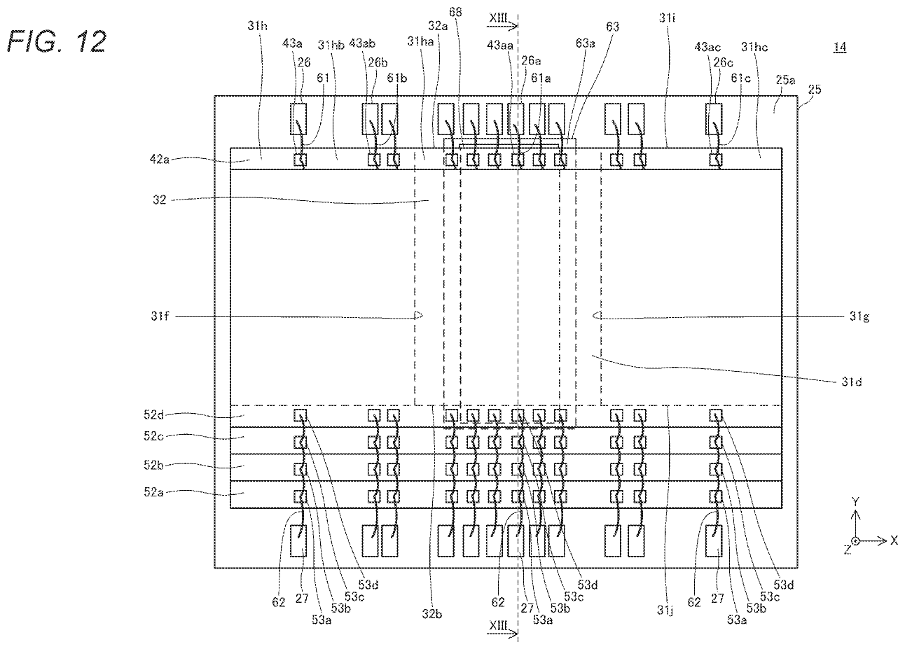

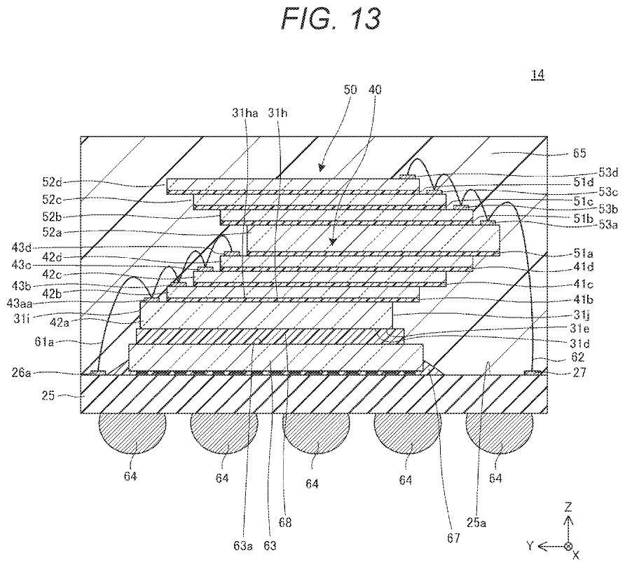

A semiconductor device according to a fifth embodiment will be described. FIG. 12 is a plan view in which a semiconductor device according to the fifth embodiment is seen from above. FIG. 13 is a cross-sectional view along a section line XIII-XIII shown in FIG. 12. As shown in FIGS. 12 and 13, compared with the semiconductor device 10 shown in FIGS. 1 to 5, the semiconductor device 14 differs from the semiconductor device 10 according to the first embodiment in that portions of the semiconductor chip 63 protrude from the hole portion 32 through the aperture portions 32a and 32b, respectively.

In some examples, a Y-axis direction width may decrease due to integration (miniaturization) of the semiconductor chips 42 and 52 improving. When the width of the semiconductor chip 42a becomes small, both of the +Y-axis and −Y-axis direction ends of the semiconductor chip 63 may be allowed to protrude from the hole portion 32 through the aperture portions 32a and 32b, respectively.

A portion the face 63a protrudes in the +Y-axis direction from the semiconductor chip 42a when the semiconductor chip 63 is seen in plan view in a direction orthogonal to the face 63a. That is, a portion of the semiconductor chip 63 is exposed by protruding from the hole portion 32 through the aperture portion 32a.

Also, when seen in plan view, a portion of the face 63a also protrudes from the semiconductor chip 42a in the −Y-axis direction. That is, a portion of the semiconductor chip 63 is exposed by protruding from the hole portion 32 through the aperture portion 32b.

In certain example embodiments, a configuration in which the groove portion 31d is formed in the Y-axis direction is described, but this is not limiting. A configuration in which the groove portion 31d is formed in any other direction may be adopted.

In certain example embodiments, a configuration in which the stacked chip body 40 is formed in a stepped shape that deviates more the farther upward the semiconductor chip 42 is in the stack is described, but this is not limiting. A configuration in which the stacked chip body 40 is formed in such a way that both the X-axis direction and the Y-axis direction end faces of each semiconductor chip 42 coincide, without each semiconductor chip 42 being deviated (offset) in the Y-axis direction may be adopted. The same applies to the stacked chip body 50.

In the certain example embodiments, a configuration in which the other semiconductor chips 42 are stacked above the semiconductor chip 42a is described, but this is not limiting. A configuration without any other semiconductor chips 42 being stacked above the semiconductor chip 42a may be adopted.

In certain example the embodiments, a configuration in which four semiconductor chips 42 are stacked in the stacked chip body 40 is described, but this is not limiting. A configuration with any number of stacked semiconductor chips 42 in the stacked chip body 40 may be adopted. In the same way, a configuration with any number of stacked semiconductor chips 52 in the stacked chip body 50 may be adopted.

In certain example embodiments, a configuration in which the semiconductor chip 42 in the stacked chip body 40 is electrically connected to the wiring substrate 25 by the bonding wire 61a is described, but this is not limiting. A configuration in which the semiconductor chip 42 is electrically connected to the wiring substrate 25 using another connection method may be adopted. For example, the semiconductor chip 42a can be electrically connected to the wiring substrate 25 by a flip chip connection or the like. The semiconductor chips 42b to 42d can be electrically connected to the wiring substrate 25 using a through-silicon via that penetrates the semiconductor chip 42a, or the like.

A semiconductor device manufacturing method according to the present disclosure is such that a semiconductor memory in which an electrode is provided on a first face of a semiconductor wafer is formed, a first bonding layer is disposed on a second face of the semiconductor wafer, a groove portion is formed by removing one portion of the first bonding layer and one portion of the second face of the semiconductor wafer, a semiconductor memory chip is formed by dicing the semiconductor wafer, a semiconductor memory controller chip is disposed on a wiring substrate, a second bonding layer is disposed on the semiconductor memory controller chip, the semiconductor memory chip is disposed on the wiring substrate in such a way that a bottom face of the groove portion formed in the semiconductor memory chip and the second bonding layer on the semiconductor memory controller chip come into contact and the wiring substrate and the first bonding layer come into contact, and at least the semiconductor memory chip is sealed using a sealing resin.

A semiconductor device according to the present disclosure includes a first semiconductor chip, which is a first semiconductor chip having a main face in which a groove portion that divides the main face into a first face and a second face is formed, a wiring substrate having a third face that opposes the first face and the second face of the first semiconductor chip, a first bonding layer provided between the first face of the first semiconductor chip and the third face of the wiring substrate, a second bonding layer provided between the second face of the first semiconductor chip and the third face of the wiring substrate, a second semiconductor chip of which at least one portion is disposed in a hole portion, which is a hole portion formed by the groove portion of the first semiconductor chip and the third face of the wiring substrate and which has a first aperture portion and a second aperture portion at either end, a third bonding layer provided between at least one portion of a bottom face of the groove portion and at least one portion of a fourth face of the second semiconductor chip that opposes the bottom face, and a sealing resin that seals at least the first semiconductor chip, in which the main face is rectangular, the groove portion divides the main face in such a way that the first face and the second face are rectangular, an area of the first face and an area of the second face are approximately the same, and the groove portion extends approximately parallel to a short side of the rectangle.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device, comprising:
a wiring substrate;
a first semiconductor chip having a first surface facing the wiring substrate, the first surface having a groove, the groove extending across the first surface and dividing the first surface into a first portion and a second portion;
a first bonding layer between the first portion of the first surface and the wiring substrate;
a second bonding layer between the second portion of the first surface and the wiring substrate;
a second semiconductor chip on the wiring substrate, the second semiconductor chip having a portion inside the groove of the first semiconductor chip; and
a third bonding layer between a bottom of the groove and a second surface of the second semiconductor chip.

2. The semiconductor device according to claim 1, further comprising:
a sealing resin that covers the first semiconductor chip.

3. The semiconductor device according to claim 1, wherein
the first semiconductor chip is rectangular in plan view, and
the groove extends from one outer edge of the first semiconductor chip to another outer edge of the first semiconductor chip.

4. The semiconductor device according to claim 1, wherein the third bonding layer is a die attach film.

5. The semiconductor device according to claim 1, further comprising:
a first substrate electrode on the wiring substrate at a position facing the second semiconductor chip; and
a first chip electrode on a surface of the second semiconductor chip facing the wiring substrate, the first chip electrode mounted to the first substrate electrode.

6. The semiconductor device according to claim 5, further comprising:
a second chip electrode on a third surface of the first semiconductor chip on a side of the first semiconductor chip opposite to that of the first surface; and
a second substrate electrode on the wiring substrate at a position not facing the first semiconductor chip; and
a first bonding that connects the second chip electrode to the second substrate electrode.

7. The semiconductor device according to claim 6, further comprising:
a third semiconductor chip on the third surface of the first semiconductor chip.

8. The semiconductor device according to claim 7, further comprising:
a third chip electrode on the third surface of the first semiconductor chip;
a third substrate electrode on the wiring substrate; and
a second bonding wiring that connects the third chip electrode and the third substrate electrode.

9. The semiconductor device according to claim 8, wherein the second chip electrode and the third chip electrode are near an outer edge of the second surface of the first semiconductor chip and above the groove.

10. The semiconductor device according to claim 1, further comprising:
a third semiconductor chip provided on a second surface of the first semiconductor chip on a side of the first semiconductor chip opposite to that of the first surface.

11. The semiconductor device according to claim 1, wherein the sealing resin fills at least a part of the groove.

12. The semiconductor device according to claim 1, wherein the sealing resin contacts an outer edge of the third bonding layer.

13. The semiconductor device according to claim 1, wherein a portion of the third bonding layer protrudes beyond an outer edge of the second semiconductor chip when seen in plan view in a direction perpendicular to the first surface.

14. The semiconductor device according to claim 1, wherein a portion of the second semiconductor chip extends from the groove to a position beyond an outer edge of the first semiconductor chip.

15. The semiconductor device according to claim 14, further comprising:
a spacer in the groove and spaced from the second semiconductor chip;
a fourth bonding layer between the spacer and the wiring substrate; and
a fifth bonding layer between the spacer and the bottom of the groove.

16. The semiconductor device according to claim 1, wherein the second semiconductor chip protrudes outward from each end of the groove.

17. The semiconductor device according to claim 1, wherein the first semiconductor chip is a semiconductor memory chip.

18. The semiconductor device according to claim 17, wherein the second semiconductor chip is a semiconductor memory controller chip.

19. The semiconductor device according to claim 1, wherein the second semiconductor chip is a semiconductor memory controller chip.
